(19) United States
(12) Patent Application Publication
(10) Pub. No.: US 2006/0121307 A1
(43) Pub. Date: Jun. 8, 2006

(54) Film deposition method

(75) Inventors: Koumei Matsuzawa, Uodu-shi (JP); Hiroshi Sato, Nirasaki-shi (JP); Takayuki Komiya, Nirasaki-shi (JP); Eiichi Kondoh, Kai-Shi (JP); Kenji Matsumoto, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignees: TOKYO ELECTRON LIMITED, Minato-Ku (JP); EIICHI KONDOH, Kai-Shi (JP)

(21) Appl. No.: 11/250,532

(22) Filed: Oct. 17, 2005

(30) Foreign Application Priority Data
Oct. 22, 2004 (JP) 2004-308286

(51) Int. Cl. C23C 16/00; B32B 15/00; C23C 14/32

(52) U.S. Cl. 428/662; 427/248.1; 204/192.1; 428/674

(57) ABSTRACT

In a film deposition method which forms a Cu film on a Cu diffusion preventing film formed on a substrate, a contact film which is provided for adhering the Cu film to the Cu diffusion preventing film is formed on the Cu diffusion preventing film. A processing medium in which a precursor is dissolved in a medium of a supercritical state is supplied to the substrate so that the Cu film is formed on the contact film.

### CROSS-REFERENCE TO RELATED APPLICATION

This application is based upon and claims the benefit of priority from Japanese patent application No. 2004-308286, filed on Oct. 22, 2004, the entire contents of which are incorporated herein by reference.

### TECHNICAL FIELD

The present invention generally relates to a film deposition method, and more particularly to a film deposition method of a Cu film.

### BACKGROUND OF THE INVENTION

In recent years, with high performance of semiconductor devices, the integration of semiconductor devices becomes higher and higher and the demand for fine-pattern wiring is remarkable. The development is going to progress with the wiring rule on the order of 0.1 micrometers or less. In addition, copper (Cu) which has a low resistance with little influence of wiring delay is used as the wiring material.

Therefore, the combination of Cu film formation technology and fine-pattern wiring technology becomes important for the fine-pattern multilayer interconnection technology in recent years.

As for the film deposition method of Cu, the sputtering method, the CVD (chemical vapor deposition) method, the plating method, etc. are generally known. However, when fine-pattern wiring is taken into consideration, the coverage of each method is limited, and it is very difficult for each method to efficiently form a Cu film in a fine pattern with a high aspect ratio of 0.1 micrometers or less.

To obviate the problem, the method for film deposition of Cu using a medium of a supercritical state has been proposed as a method of efficiently forming a Cu film in a fine pattern.

If a substance in a supercritical state is used as the medium for dissolving a precursor for film formation, the solubility of the precursor can be maintained at a level higher than the level of a gaseous medium since the substance in the supercritical state has the density and the solubility which resemble those of a fluid medium. Moreover, by using the diffusion coefficient which resembles that of a gaseous medium, it is possible to introduce the precursor to the substrate more efficiently than the medium of a fluid.

Therefore, in the case of the film formation using a processing medium in which the precursor is dissolved in the medium of the supercritical state, it is possible to perform appropriate film formation with a high film formation speed and a good coverage to fine pattern.

For example, the method of forming a Cu film in which a processing medium is formed by dissolving a precursor for Cu film formation using CO₂ of a supercritical state has been proposed. For example, see Japanese Laid-Open Patent Application No. 10-229084.

In the case of the processing medium using CO₂ of the supercritical state, the solubility of the Cu film formation precursor which is a precursor compound containing Cu is high, the viscosity is low, and the diffusibility is high. The Cu film formation to a fine pattern can be attained with a high aspect ratio and a good coverage.

On the other hand, when Cu wiring is used for the wiring of a semiconductor device etc, there is a possibility that Cu diffuses into the insulating layer formed in the circumference of the Cu wiring. The commonly used process to avoid this is to form a Cu diffusion preventing film (which is also called a barrier film, a ground film, etc.) between the Cu wiring and the insulating layer. For example, see “Deposition of Conformal Copper and Nickel Films from Supercritical Carbon Dioxide” SCIENCE vol. 294, Oct. 5, 2001.

However, in the case where the conventional method is used, the Cu film which is formed using the medium of the supercritical state has a poor adhesion to the Cu diffusion preventing film (for example, a Ta film, a TaN film, etc.). For this reason, delamination between the Cu film and the Cu diffusion preventing film may occur, which will cause the lowering of the reliability of the semiconductor device manufactured.

When compared with the Cu film which is formed through a combination of the plating method, the CVD method and the sputtering method which are conventionally used, the Cu film which is formed using the medium of the supercritical state has a poor adhesion to the Cu diffusion preventing film, and the difficulty in forming the Cu film on the Cu diffusion preventing film may take place.

### SUMMARY OF THE INVENTION

A general object of the present invention is to provide a novel, useful film deposition method in which the above-mentioned problems are eliminated.

A more specific object of the present invention is to provide a film deposition method which is capable of forming a Cu film, even in a very fine pattern, on the Cu diffusion preventing film, the Cu film having good adhesion to the Cu diffusion preventing film.

In order to achieve the above-mentioned objects, the present invention provides a film deposition method which forms a Cu film on a Cu diffusion preventing film formed on a substrate, the film deposition method comprising the steps of: forming a contact film, which is provided for adhering the Cu film to the Cu diffusion preventing film, on the Cu diffusion preventing film; and supplying a processing medium in which a precursor is dissolved in a medium of a supercritical state, to the substrate so that the Cu film is formed on the contact film.

Moreover, the above-mentioned film deposition method may be configured so that the step of supplying the processing medium comprises: heating the substrate inside a processing container containing a holding stand holding the substrate therein; supplying the processing medium into the processing container; and forming the Cu film on the contact film with the supplied processing medium.

Moreover, the above-mentioned film deposition method may be configured so that the Cu diffusion preventing film contains Ta.

Moreover, the above-mentioned film deposition method may be configured so that the medium of the supercritical state contains CO₂ of a supercritical state.

Moreover, the above-mentioned film deposition method may be configured so that the precursor is made of a material chosen from a group including Cu(hfac)₂, Cu(acac)₂, Cu(dpm)₂, Cu(dibm)₂, Cu(ibpm)₂, Cu(hfac)TMVS, and Cu(hfac)COD, and H₂ is added to the processing medium.

Moreover, the above-mentioned film deposition method may be configured so that the contact film contains a metal which is any of platinum group elements, iron group elements, and Cu.

Moreover, the above-mentioned film deposition method may be configured so that the contact film is formed by using either a CVD method or a PVD method.

Moreover, the above-mentioned film deposition method may be configured so that the contact film contains Cu and an element which constitutes the Cu diffusion preventing film.

Moreover, the above-mentioned film deposition method may be configured so that the element is a metallic element.

Moreover, the above-mentioned film deposition method may be configured so that the metallic element is Ta.

Moreover, the above-mentioned film deposition method may be configured so that the contact film is formed by supplying to the substrate a second processing medium in which a second precursor is dissolved in a second medium of a supercritical state.

Moreover, the above-mentioned film deposition method may be configured so that the second precursor is made of a material chosen from a group including Cu(hfac)₂, Cu(acac)₂, Cu(dpm)₂, Cu(dibm)₂, Cu(ibpm)₂, Cu(hfac)TMVS, and Cu(hfac)COD.

Moreover, the above-mentioned film deposition method may be configured so that the second precursor is made of a material chosen from a group including TaCl₅, TaF₅, TaBr₅, TaI₅, Ta(NC(CH₃)₃) (N(C₂H₅)₂)₃, Ta(NC(CH₃)₂C₂H₅)(N(CH₃)₂)₃, (C₅H₅)₂TaH₃, and (C₅H₅)₂TaCl₃.

Furthermore, in order to achieve the above-mentioned objects, the present invention provides a computer-readable recording medium recording a program embodied therein for causing a computer to execute the above-mentioned film deposition method.

According to the film deposition method of the present invention, it is possible that the Cu film formed on the Cu diffusion preventing film has good adhesion to the Cu diffusion preventing film even when the Cu film is provided in a very fine pattern.

### BRIEF DESCRIPTION OF THE DRAWINGS

FIG. 1 is a flowchart for explaining a film deposition method in an embodiment of the invention.

FIG. 2 is a diagram showing the composition of a film deposition system which is used for the film deposition method of the embodiment.

FIG. 3A, FIG. 3B and FIG. 3C are diagrams for explaining an example of the method of manufacturing a semiconductor device using the film deposition method of the embodiment.

FIG. 4A and FIG. 4B are diagrams for explaining the example of the method of manufacturing the semiconductor device using the film deposition method of the embodiment.

### DETAILED DESCRIPTION OF PREFERRED EMBODIMENTS

A description will now be given of an embodiment of the invention with reference to the accompanying drawings.

The film deposition method of this embodiment is to form a Cu film which is used for the wiring of a semiconductor device. According to the film deposition method of this embodiment, it is possible that a Cu film is formed on the Cu diffusion preventing film formed on the substrate, and the Cu film has good adhesion to the Cu diffusion preventing film.

By using a processing medium in which a precursor is dissolved in a medium of a supercritical state and supplying the processing medium to a substrate, a Cu film is thus formed on the substrate according to the film deposition method of this embodiment.

Since the solubility of the precursor in the medium of the supercritical state is high, and the viscosity is low and the diffusibility is high, the Cu film formation in a very fine pattern with a high aspect ratio which is, for example, on the order of 0.1 micrometer or less can be attained with good coverage. It is possible to form Cu films and make the Cu films into fine circuit patterns, such as via wiring and trench wiring.

However, when a Cu film is formed using the processing medium in which the precursor is dissolved in the medium of the supercritical state, there has been a problem that the Cu film has poor adhesion to the Cu diffusion preventing film.

To obviate the problem, a contact film is formed on the Cu diffusion preventing film, and a Cu film is formed on the contact film concerned according to the film deposition method of this embodiment.

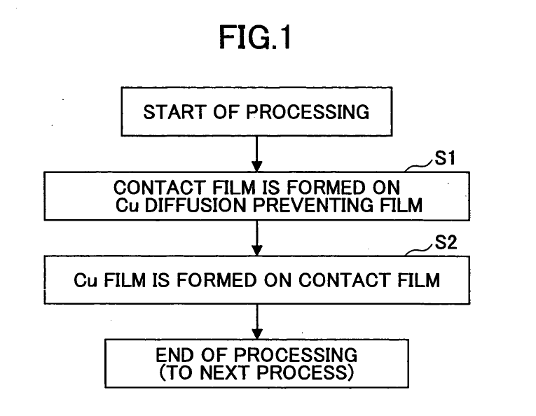

FIG. 1 is a flowchart for explaining the film deposition method of this embodiment.

Upon start of the processing shown in FIG. 1, at step S1, a contact film is formed on a Cu diffusion preventing film which is formed on the substrate. This contact film has the features that it has a good adhesion to the Cu diffusion preventing film, and it has a good adhesion to a Cu film which is subsequently formed at a next step using a medium of a supercritical state.

Next, a Cu film is formed at step S2 on the contact film which has been formed at step S1. This Cu film is formed by supplying a processing medium in which a precursor is dissolved in a medium of a supercritical state to the substrate, which will be described later.

After the Cu film is formed at this step, a CMP (chemical mechanical polishing) process may be performed, if needed, and, after the CMP process is performed, the process of forming an upper wiring structure further may be performed, so that a semiconductor device having a multilayer interconnection structure is formed.

Subsequently, a tape is attached to the surface of the Cu film formed on the contact film according to the above-described method, and a peel-off test in which the tape is peeled away from the Cu film surface is conducted in order to evaluate the adhesion of the Cu film. In this case, the Cu diffusion preventing film is formed by using the PVD method.

Various materials may be used as a material of the contact film. For example, it is desirable that the contact film is made of a material containing any metal chosen from among platinum group elements (Ru, Rh, Pd, Os, Ir, Pt), iron group elements (Fe, Co, Ni), and Cu, since the adhesion between the CU film and the Cu diffusion preventing film improves.

The contact film of such materials may be formed through a PVD (physical vapor deposition) method or a CVD (chemical vapor deposition) method. In this case, it is desirable that the film formation method using the medium of the supercritical state is not used to form the contact film of Cu. It is desirable that any of the PVD method (for example, the sputtering method), the CVD method or the plating method is used for the film formation. If it is formed through the sputtering method which is the PVD method, the adhesion becomes better.

For example, when any metal of platinum group elements (Ru, Rh, Pd, Os, Ir, Pt), iron group elements (Fe, Co, Ni), and Cu is used for the contact film, the Cu diffusion preventing film is protected by the above-mentioned metal, and it is possible to prevent the oxidation of the Cu diffusion preventing film. For example, if a film containing Ta is used in the Cu diffusion preventing film and the Cu diffusion preventing film is exposed to the ambient atmosphere, the Ta film will easily oxidize and the Ta oxide film will be formed on the Cu diffusion preventing film. The Ta oxide film has a poor adhesion to the Cu film, which may cause the delamination to arise between the Cu film and the Cu diffusion preventing film.

In this embodiment, the contact film is formed on the Cu diffusion preventing film, and oxidation of the Cu diffusion preventing film is prevented. Thus, it is possible to prevent formation of the Ta oxide film which has a poor adhesion to the Cu film.

Platinum group elements (Ru, Rh, Pd, Os, Ir, Pt), iron group elements (Fe, Co, Ni), and Cu do not oxidize easily when compared with Ta. And, in the case of Cu, even if the surface of the contact film oxidizes, at a early state in the process which forms the Cu film on the contact film, the oxide film formed in the surface is reduced by the reducing agent (for example, H₂) used for the film formation. Thus, it is possible to eliminate the influence of the oxide film which is the factor which lowers the adhesion.

Also, the oxide of Ru, Ir, Rh, Pd or Os has a specific resistance which is smaller than that of the oxide of Ta. When the contact film made of any of Ru, Ir, Rh, Pd, or Os is used, even if the surface of the contact film oxidizes, its specific resistance is small and such contact film is desirable as a Cu diffusion preventing film of the Cu wiring.

Moreover, other materials may be used for the contact film which attains good adhesion between the Cu film and the Cu diffusion preventing film. For example, it is desirable that the contact film is made of a material containing Cu and an element which constitutes the Cu diffusion preventing film. In this case, both the adhesion of the contact film and the Cu film and the adhesion of the contact film and the Cu diffusion preventing film become good. That is, it is desirable that the contact film is formed so that it may have an intermediate characteristic between the Cu diffusion preventing film and the Cu film, which will create good adhesion. In this case, it is preferred that the contact film is made to contain a metallic element (for example, Ta) which constitutes the Cu diffusion preventing film. This makes the adhesion of the contact film and the Cu diffusion preventing film good.

As in the above-described manner, the contact film made of an alloy containing a metallic element selected from among platinum group elements, iron group elements, and Cu may be used.

Furthermore, it is preferred that the contact film is made such that the rate of the component which constitutes the contact film concerned varies in a thickness direction of the contact film, or in the thickness direction from the side of the Cu diffusion preventing film to the side of the Cu film, which will make the adhesion better.

For example, it is preferred that the contact film is made such that the rate of Cu contained in the contact film increases in the thickness direction from the Cu diffusion preventing film side to the Cu film side. Moreover, it is preferred that the contact film is made such that the rate of a metallic element (for example, Ta) which constitutes the Cu diffusion preventing film decreases in the thickness direction from the Cu diffusion preventing film side to the Cu film side, which will make the adhesion still better.

The above-mentioned contact film which contains Cu and the element which constitutes the Cu diffusion preventing film may be formed by using various methods. For example, it is possible to form the contact film by using the sputtering method (which is a PVD method). Alternatively, the contact film may be formed by using either the medium of the supercritical state as in the case where the Cu film is formed, or the ALD (atomic layer deposition) method, which will be described later.

When the ALD method is used in order to form the contact film, a first processing gas is supplied to the substrate so that the first processing gas is adsorbed to the substrate. Then, the excessive part of the first processing gas is removed, and a second processing gas is further supplied to the substrate, so that the second processing gas is reacted with the first processing gas adsorbed to the substrate. Then, the excessive part of the second processing gas is removed. The above-mentioned procedure is repeated. By using the ALD method, it is possible to form the contact film with high quality and little impurity on the level of atomic layer or molecular layer on the substrate surface, with good uniformity within the substrate.

Specifically, the contact film containing Ta and Cu may be formed by using the above-mentioned ALD method.

Alternatively, the above-mentioned contact film containing Cu and the element which constitutes the Cu diffusion preventing film may be formed by using the film formation method which is the same as the Cu film forming method at the next step which supplies the processing medium in which the precursor is dissolved in the medium of the supercritical state to the substrate.

In such alternative case, it is possible that the formation of the contact film and the formation of the Cu film be carried out continuously with the same processing container, and the efficiency of the film formation can be increased.

Since the substrate is not exposed to the atmosphere if the above-mentioned continuous film formation is performed, it is possible to eliminate the factor, such as formation of an oxide film, and the adhesion of the contact film and the Cu film can be made still better.

In this case, the precursor for making the contact film contain Cu may be made of Cu(hfac)₂ (“hfac” denotes hexafluoroacetylacetonato), and the precursor for making the contact film contain Ta may be made of TaCl₅. However, the present invention is not limited to these examples, and various other precursors may be used instead.

Alternatively, other than TaCl₅, the precursor for making the contact film contain Ta may be made of a halogenated compound containing Ta, which is, for example, TaF₅, TaBr₅, TaI₅, etc.

Alternatively, besides the halogenated compound, the precursor for making the contact film contain Ta may be made of an organic compound which is, for example, TBTDET (“TBTDET” denotes Ta(NC(CH₃)₃)(N(C₂H₅)₂)₃), TAIMATA (which is a registered trademark and “TAIMATA” denotes Ta(NC(CH₃)₂C₂H₅)(N(CH₃)₂)₃), (C₅H₅)₂TaH₃, (C₅H₅)₂TaCl₃, etc.

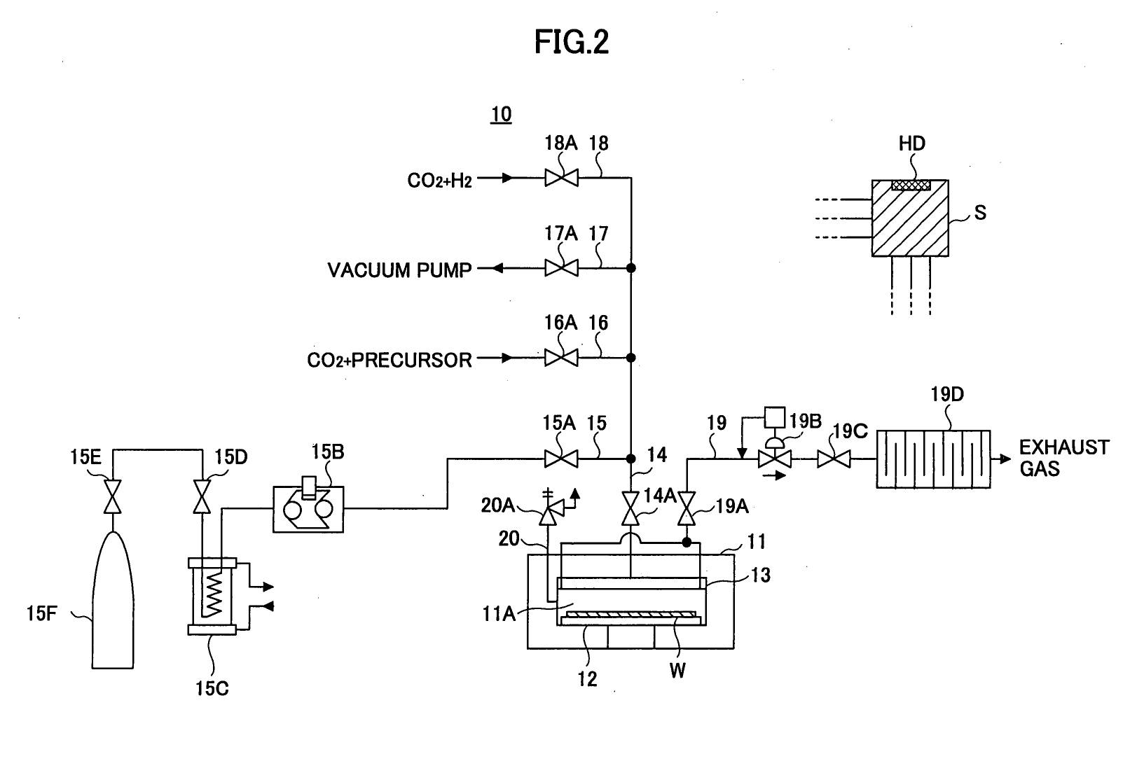

Next, a film deposition system which forms a Cu film on the contact film using a medium of a supercritical state will be described with reference to FIG. 2.

FIG. 2 shows the composition of the film deposition system which is used for forming the Cu film at step S2 of the flowchart of FIG. 1.

As shown in FIG. 2, the film deposition system 10 comprises a processing container 11 in which a processing space 11A is formed, and a holding stand 12 which holds the substrate W is disposed inside the processing container 11A. The holding stand 12 is provided with a heating unit (not shown), such as a heater. Thus, it is possible to heat the substrate W laid on the mounting base.

Inside the processing container 11, a supplying part 13 in which a plurality of supply holes (which have the shower head structure) are formed to supply the medium of the supercritical state, or the processing medium in which the precursor is dissolved in the medium of the supercritical state, to the processing space 11A is disposed on the side of the processing container 11 which faces the holding stand 12.

A supply line 14 to which a valve 14A is attached is connected to the supplying part 13, and it is arranged so that the medium of the supercritical state or the processing medium in which the precursor is dissolved in the medium of the supercritical state is supplied to the processing space 11A via the supplying part 13 from the supply line 14.

A supply line 15 to which a valve 15A is attached is connected to the supply line 14 to supply the medium of the supercritical state to the supply line 14. A supply line 16 to which a valve 16A is attached is connected to the supply line 14 to supply the precursor to the supply line 14. Furthermore, a supply line 18 to which a valve 18A is attached is connected to the supply line 14 to supply the gas, such as a reducing agent, required for the film formation processing, to the supply line 14.

Moreover, a supply line 17 to which a valve 17A is attached is connected at one end to the supply line 14, and this supply line 17 is connected at the other end to a vacuum pump (not shown). If needed, the evacuation of the processing space 11A or the evacuation of the supply line 14 is carried out by the vacuum pump through the supply line 17.

A cylinder 15F of CO₂ which is the source medium of the medium of the supercritical state is connected to the supply line 15 via a pressurizing pump 15B, a condenser 15C, and valves 15D and 15E. The CO₂ supplied from the cylinder 15F is cooled by the condenser 15C, and further pressurized by the pressurizing pump 15B, so that it is made into the conditions of a predetermined pressure and a predetermined temperature. The CO₂ is used as the medium of the supercritical state, and the medium of the supercritical state is supplied to the processing space 11A.

For example, in the case of CO₂, the critical point (the point at which the supercritical state is reached) is the temperature of 31.0 degrees C. and the pressure of 7.38 MPa. CO₂ is set in the supercritical state when the temperature and the pressure thereof exceed the critical point.

From the supply line 16, the precursor (for example, Cu(hfac)₂) which is dissolved in CO₂ of the supercritical state is supplied to the processing space 11A. From the supply line 18, the H₂ gas which is the reducing agent is supplied to the processing space 11A. In this case, H₂ which is the reducing agent may be supplied together with CO₂ of the supercritical state.

A discharge line 19 to which the valves 19A and 19C and the trap 19D are attached is connected to the processing container 11, so that the processing medium and the medium of the supercritical state supplied to the processing space 11A are discharged. The discharge line 19 is arranged so that the precursor which is dissolved in the processing medium is captured by the trap 19D and the resulting processing medium is discharged outside the processing space. A pressure control valve 19B is further attached to the discharge line 19. By controlling the pressure of discharge line 19 to a desired value, it is possible to discharge the processing medium or the medium of the supercritical state supplied to the processing space 11A.

Moreover, an explosion-proof line 20 and an explosion-proof valve 20A are provided in the processing space 11A, in order to prevent the pressure of the processing space 11A from becoming higher than a pressure which the processing container 11 can withstand.

For example, when forming a Cu film on the substrate by using the above-mentioned film deposition system 10, the Cu film can be formed by controlling the film deposition system 10 as follows.

First, upon start of the film deposition processing, the substrate is delivered to the processing space 11A from the gate valve (not illustrated), and the wafer W which is the substrate is laid on the holding stand 12.

Next, after the evacuation of the processing space 11A is performed through the supply line 17, the substrate is heated by the heater provided in the holding stand 12, and the temperature of the substrate is set at 300 degrees C.

Next, from the supply line 15, CO₂ is introduced into the processing space 11A, and the pressure in the processing space 11A is raised. In this case, the CO₂ being introduced may beforehand be made into the supercritical state. Alternatively, the CO₂ may be made into the supercritical state by continuously supplying CO₂ of a fluid state to the processing container 11 and raising the pressure of the supplied CO₂, or by raising the temperature of CO₂ in the processing space 11A.

At the same time as the rise of the pressure of the processing space 11A, or before the rise of the pressure of the processing space 11A, H₂ may be introduced into the processing space 11A from the supply line 18, so that it is mixed with the processing medium, and in addition to the processing medium, the H₂ concerned is used. The pressure of the processing space 11A is set to 15 MPa, for example.

Next, the processing medium in which Cu(hfac)₂ which is the precursor is dissolved in the medium of the supercritical state is supplied from the supply line 16 to the substrate on the holding stand in the processing space 11A. In this case, when the precursor is thermally decomposed on the substrate heated to 300 degrees C., a Cu film is formed on the substrate.

Since CO₂ of the supercritical state under the above pressure has a high solubility of the precursor used for film formation and the processing medium in which the precursor is dissolved has a high diffusibility, the film formation speed is high and it is possible to perform appropriate Cu film formation with a good coverage to a fine pattern. It is possible to form a Cu film with a good filling nature at high film formation speed, without forming a void in a fine pattern with a line width of 0.1 micrometer or less formed with the insulating layer.

After the film formation is performed for a predetermined time, the supply of the processing medium is stopped, the valves 19A and 19C are opened, and the processing medium of the processing space 11A is discharged from the discharge line 19.

In this case, the pressure of the processing space 11A is controlled by using the pressure control valve 19B to a predetermined pressure so that the pressure of the medium being discharged does not become too high.

In this case, if needed, CO₂ is supplied from the supply line 15 to the processing space 11A and the processing space 11A is purged.

After the purging is completed, the pressure of the processing space 11A is returned to the atmospheric pressure, and the film formation is completed.

In the above-mentioned embodiment, Cu(hfac)₂ is used as a precursor for Cu film formation. However, the precursor is not limited to this embodiment. Alternatively, a metal complex addition product (adduct) in which the organic silane with electron-donative binding or the molecule containing at least one of the groups containing carbohydrate is added to a metal complex in which two beta-diketonato ligands are coordinated to the divalent copper ion or a metal complex in which one beta-diketonato ligand is coordinated to the monovalent copper ion may be used as the precursor for Cu film formation.

Alternatively, an organometallic complex containing at least one of the divalent copper ion and the monovalent copper ion, an organometallic complex addition product, or an organic mixture containing at least one of the organometallic complex and the organometallic complex addition product, etc. may be used as the precursor for Cu film formation.

For example,.the precursor for Cu film formation may be made of a material chosen from the group including Cu(acac)₂, Cu(dpm)₂, Cu(dibm)₂, Cu(ibpm)₂, Cu(hfac)TMVS, and Cu(hfac)COD, wherein “acac” denotes acetylacetonato, “dpm” denotes dipivaloylmethanato, “dibm” denotes diisobutyrylmethanato, “ibpm” denotes isobutyrylpivaloylmethanato, “TMVS” denotes trimethylvinylsilane, and “COD” denotes 1,5-cyclooctadiene. In the case where such precursor is used, it is also possible to obtain the same result as that in the case where Cu(hfac)₂ is used.

Moreover, the film formed on the wafer is not limited to Cu film in the above-described embodiment. Alternatively, any of the metal films or the metallic compound films, such as tantalum, tantalum nitride, titanium nitride, tungsten, and tungsten nitride, may be formed on the wafer, instead of Cu film. These metal films and metallic compound films may be used as the Cu diffusion preventing film in the case of forming Cu wiring in a fine pattern, and it is possible to form the Cu diffusion preventing film in the fine pattern efficiently. In the case where such Cu diffusion preventing film is formed, it is also possible to obtain the same result as that in the case where the CU film is formed in the above embodiment.

The medium of the supercritical state is not limited to CO₂ in the above-described embodiment. Alternatively, NH₃ or others may be used instead. In the case where NH₃ is used as the medium of the supercritical state, it is possible to form a metal nitride film.

The film deposition system 10 in the above-mentioned embodiment has a control unit S comprising a recording medium HD, such as a hard disk, and a computer (or CPU) which is not illustrated.

The CPU of the control unit S controls operation of the film deposition system 10 in accordance with a program stored in the recording medium HD. For example, in accordance with the program, the control unit S controls operation of the valves in the film deposition system 10 such that the medium of the supercritical state is supplied to the processing container, or the exhaust gas in the processing container is discharged. Thus, the program enables the control unit of the film deposition system to perform the operation related to the film formation processing.

The program for the film formation processing which is stored in the recording medium may be called a recipe. The operation for film formation of the film deposition system described above is carried out by the control unit S in accordance with the program (recipe) stored in the recording medium HD.

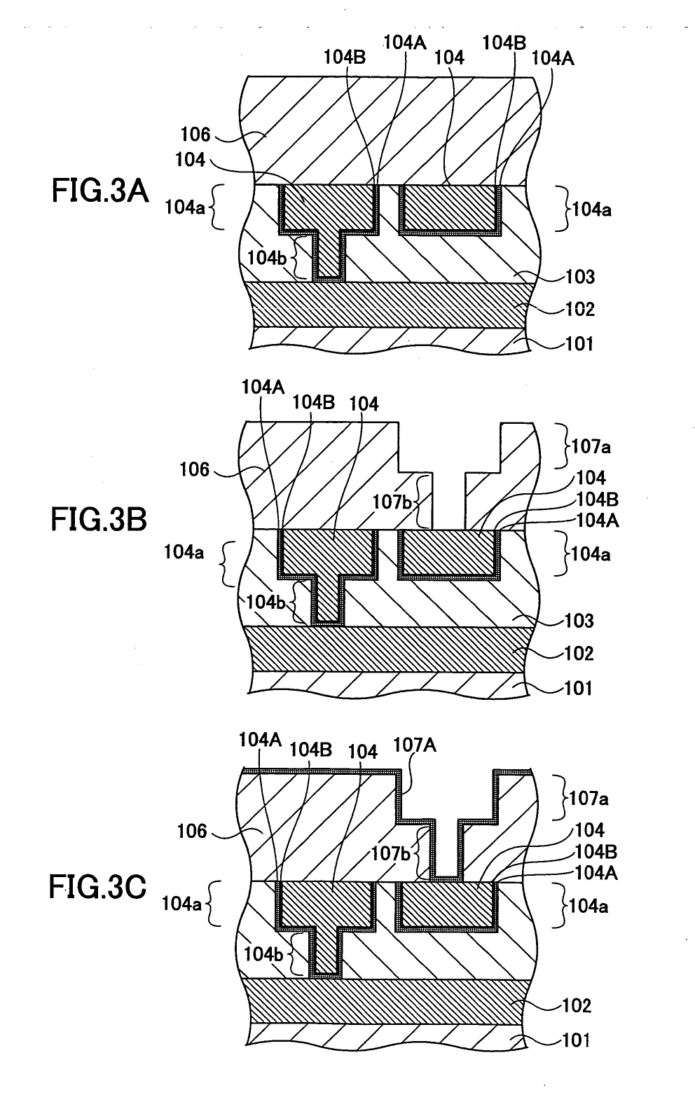

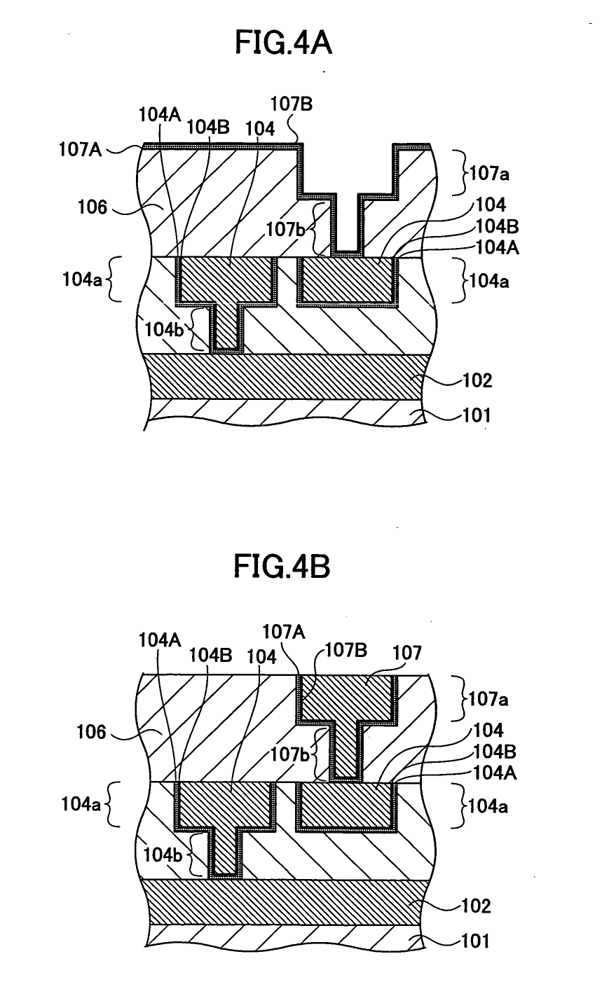

Next, an example of the method of manufacturing a semiconductor device using the film deposition method of the above-mentioned embodiment will be described with reference to FIG. 3A through FIG. 4B.

FIG. 3A, FIG. 3B, FIG. 3C, FIG. 4A and FIG. 4B show the procedure for the example of the method of manufacturing the semiconductor device using the film deposition method of the embodiment.

As shown in FIG. 3A, the insulating layer 101 which is made of silicon oxide is formed to cover the elements (not shown), such as MOS transistors, formed on the semiconductor substrate which is made of silicon. The wiring layer (not shown) which is made of W (tungsten) and electrically connected to the above-mentioned elements, and the wiring layer 102 which is made of Cu and electrically connected to the W wiring layer are formed.

On the silicon oxide layer 101, the first insulating layer 103 is formed so that the wiring layer 102 may be covered by the first insulating layer 103.

In the insulating layer 103, the groove part 104a and the hole part 104b are formed. The wiring portion 104 in which the trench wiring and the via wiring is formed of Cu is formed is formed in the groove part 104a and the hole part 104b. This wiring portion 104 is electrically connected with the above-mentioned wiring layer 102.

The Cu diffusion preventing film 104A is formed between the first insulating layer 103 and the wiring portion 104 on the side of the first insulating layer 103, and the contact film 104B is formed between the first insulating layer 103 and the wiring portion 104 on the side of the wiring portion 104.

The Cu diffusion preventing film 104A has the function of preventing the diffusion of Cu from the wiring portion 104 to the first insulating layer 103.

Moreover, the second insulating layer 106 is formed so that the top surface of the wiring portion 104 and the first insulating layer 103 may be covered by the second insulating layer 106.

In the following embodiment, the film deposition method of the above-mentioned embodiment is applied to the second insulating layer 106, and the procedure for forming a contact film and a Cu film in the second insulating layer 106 will be described.

However, the film deposition method of the above-mentioned embodiment may also be applied to the formation of the wiring portion 104 and the contact film 104B in the first insulating layer 103.

In the process shown in FIG. 3B, the groove part 107a and the hole part 107b are formed in the second insulating layer 106 by using, for example, the dry etching method.

Next, in the process shown in FIG. 3C, the Cu diffusion preventing film 107A is formed on the top surface of the second insulating layer 106 including the inner walls of the groove part 107a and the hole part 107b, and the top surface of the wiring portion 104.

The Cu diffusion preventing film 107A in this case is made of a laminated film of a Ta film and a TaN film. The Cu diffusion preventing film 107A may be formed by using the sputtering method or the like.

However, the Cu diffusion preventing film 107A may be formed by using the method of supplying the processing medium in which the precursor is dissolved in the medium of the supercritical state with the film deposition system 10 as in the above-described embodiment.

In the latter case, it is possible to form a Cu diffusion preventing film in a fine pattern with good coverage. In this case, the precursor may be made of a material chosen from a group including TaF₅, TaCl₅, TaBr₅, TaI₅, (C₅H₅)₂TaH₃, (C₅H₅)₂TaCl₃, PDMAT (pentakis(dimethylamino)tantalum [(CH₃)₂N]₅Ta), PDEAT (pentakis(diethylamino)tantalum [(C₂H₅)₂N]₅Ta), TBTDET (Ta(NC(CH₃)₃(N(C₂H₅)₂)₃), and TAIMATA (a registered trademark, Ta(NC(CH₃)₂C₂H₅)(N(CH₃)₂)₃)). The medium of the supercritical state may be made of either CO₂ or NH₃. In this way, the Cu diffusion preventing film 107A which is made of Ta/TaN can be formed. Alternatively, the Cu diffusion preventing film may be formed by using the above-mentioned ALD method.

Next, in the process shown in FIG. 4A, the contact film 107B which is made of a Ru film is formed, by using the sputtering method, on the top surface of the Cu diffusion preventing film 107A including the inner walls of the groove part 107a and the hole part 107b.

Alternatively, the contact film in this case may contain any metallic element of platinum group elements (except Ru), iron group elements, and Cu. As in the previously described embodiment, the contact film may be made of a material containing Cu and the metallic element (for example, Ta) which constitutes the Cu diffusion preventing film. The above-mentioned contact film may be formed by using the ALD method.

Moreover, the contact film may be formed by using the method similar to that in the previously described embodiment, which uses the processing medium in which the precursor is dissolved in the medium of the supercritical state. In this case, the process which forms the contact film can be performed in the processing container which is the same as that in the subsequent process which forms the Cu film. The film formation can be completed promptly and the processing efficiency for the substrate becomes high. Moreover, the problem that the contact film formed is exposed to the atmosphere does not arise, and it is possible to eliminate the influence of oxidation of the film surface.

Next, in the process shown in FIG. 4B, the wiring portion 107 which is made of Cu is formed, by using the method as in the previously described embodiment, on the surface of the contact film 107A containing the groove part 107a and the hole part 107b.

In this case, the CO₂ of the supercritical state is used, and the CO₂ (processing medium) of the supercritical state in which the Cu film formation precursor is dissolved shows good diffusibility. The wiring portion 107 can be formed with good coverage to the bottom and side walls of the groove part 107a and the hole part 107b.

As previously described, in the case where the conventional method is used, the problem that the Cu film formed using the medium of the supercritical state has a poor adhesion to the Cu diffusion preventing film arises.

According to the present embodiment, the above problem can be eliminated, and the possibility of delamination of the wiring portion made of Cu can be lowered, and it is possible to produce a reliable semiconductor device having the multilayer interconnection structure.

Subsequently, the (2+n)th insulating layer (where n is a natural number) may be formed on the top of the second insulating layer, and it is possible to form the wiring portion made of Cu in such insulating layer by applying the film deposition method of this embodiment to that insulating layer.

In the above-described embodiment, the laminated film made of Ta/TaN is used for the Cu diffusion preventing film. However, the present invention is not limited to this embodiment. Alternatively, various Cu diffusion preventing films, other than the laminated film made of Ta/TaN, may be used instead. For example, a WN film, a W film, a laminated film of Ti and TiN, etc. may be used instead.

Moreover, the first insulating layer 103 or the second insulating layer 106 may be made of silicon oxide (SiO₂ film), fluorine addition silicon oxide (SIOF film), a SICO(H) film, etc.

The present invention is not limited to the above-described embodiments, and variations and modifications may be made without departing from the scope of the present invention.

What is claimed is:

1. A film deposition method which forms a Cu film on a Cu diffusion preventing film formed on a substrate, comprising the steps of:
forming a contact film, which is provided for adhering the Cu film to the Cu diffusion preventing film, on the Cu diffusion preventing film; and
supplying a processing medium in which a precursor is dissolved in a medium of a supercritical state, to the substrate so that the Cu film is formed on the contact film.

2. The film deposition method according to claim 1 wherein the step of supplying the processing medium comprises:
heating the substrate inside a processing container containing a holding stand holding the substrate therein;
supplying the processing medium into the processing container; and
forming the Cu film on the contact film with the supplied processing medium.

3. The film deposition method according to claim 1 wherein the Cu diffusion preventing film contains Ta.

4. The film deposition method according to claim 1 wherein the medium of the supercritical state contains CO₂ of a supercritical state.

5. The film deposition method according to claim 1 wherein the precursor is made of a material chosen from a group including Cu(hfac)₂, Cu(acac)₂, Cu(dpm)₂, Cu(dibm)₂, Cu(ibpm)₂, Cu(hfac)TMVS, and Cu(hfac)COD, and H₂ is added to the processing medium.

6. The film deposition method according to claim 1 wherein the contact film contains a metal which is any of platinum group elements, iron group elements, and Cu.

7. The film deposition method according to claim 6 wherein the contact film is formed by using either a CVD method or a PVD method.

8. The film deposition method according to claim 1 wherein the contact film contains Cu and an element which constitutes the Cu diffusion preventing film.

9. The film deposition method according to claim 8 wherein the element is a metallic element.

10. The film deposition method according to claim 9 wherein the metallic element is Ta.

11. The film deposition method according to claim 8 wherein the contact film is formed by supplying to the substrate a second processing medium in which a second precursor is dissolved in a second medium of a supercritical state.

12. The film deposition method according to claim 11 wherein the second precursor is made of a material chosen from a group including Cu(hfac)2, Cu(acac)₂, Cu(dpm)₂, Cu(dibm)₂, Cu(ibpm)₂, Cu(hfac)TMVS, and Cu (hfac) COD.

13. The film deposition method according to claim 11 wherein the second precursor is made of a material chosen from a group including TaCl₅, TaF₅, TaBr₅, TaI₅, Ta(NC(CH₃)₃)(N(C₂H₅)₂)₃, Ta(NC(CH₃)₂C₂H₅)(N(CH₃)₂)₃), (C₅H₅)₂TaH₃, and (C₅H₅)₂TaCl₃.

14. A computer-readable recording medium storing a program embodied therein for causing a computer to execute the film deposition method according to claim 1.
